(19) United States
(12) Patent Application Publication
(10) Pub. No.: US 2019/0287611 A1
(43) Pub. Date: Sep. 19, 2019

(54) RESISTIVE MEMORY DEVICE AND METHOD FOR FABRICATING THE SAME

(71) Applicant: MACRONIX INTERNATIONAL CO., LTD., Hsinchu (TW)

(72) Inventors: Po-Hao TSENG, Taichung City (TW); Feng-Min LEE, Hsinchu City (TW)

(21) Appl. No.: 15/922,995

(22) Filed: Mar. 16, 2018

(51) Int. Cl. G11C 11/56; H01L 45/00; G11C 13/00

(52) U.S. Cl. CPC G11C 11/5685; G11C 2013/0092; H01L 45/146; H01L 45/147; H01L 45/1233; H01L 45/1608; H01L 45/1666; G11C 13/0007; G11C 2213/31; G11C 2213/32; G11C 2213/33; G11C 2213/52; G11C 13/0069; G11C 13/0097; H01L 45/1253

(57) ABSTRACT

A resistive memory device includes a first electrode, a first transition metal oxide (TMO) layer, a second TMO layer and a second electrode. The first electrode includes tungsten (W). The first TMO layer is disposed on the first electrode and includes titanium (Ti). The second TMO layer is disposed on the first TMO layer and includes silicon (Si). The second electrode is disposed on the second TMO layer and does not include W. The first TMO layer has a dielectric constant greater than that of the second TMO layer.

### BACKGROUND OF THE INVENTION

### Field of the Invention

The invention relates in general to a non-volatile memory (NVM) and the method for fabricating the same, and more particularly to a resistive memory and the method for fabricating the same.

### Description of the Related Art

NVMs which can continually store information even when the supply of electricity is removed from the device containing the NVM cells. Recently, the most widespread used NVMs are charge trap flash (CTF) memory devices. However, as semiconductor features shrink in size and pitch, the CTF memory devices have its physical limitation of operation. To solve the problems, resistive memory devices are thus provided.

Resistive memory devices, such as resistive random-access memory (ReRAM) devices, that apply difference of resistance within the memory cells thereof to implementing the erase/program operation have advantages in terms of cell area, device density, power consumption, programming/erasing speed, three-dimensional integration, multi-value implementation, and the like over flash memory devices, and thus have become a most promising candidate for leading products in the future memory market.

However, a ReRAM device typically has a forming voltage higher than its operation voltage, which is unfavorable to low-voltage operation and does not provide a low-power solution to an electronic device, such as internet of things (IoT), wearable devices or portable electronic devices (e.g. notebooks (NB), tablets, smartwatches, cell phones etc.) that need to be operated at low voltage and consume smaller power for extending battery life.

Therefore, there is a need of providing an improved resistive memory and the method for fabricating the same to obviate the drawbacks encountered from the prior art.

### SUMMARY OF THE INVENTION

According to one embodiment of the present disclosure, a resistive memory device is provided, wherein the resistive memory device includes a first electrode, a first transition metal oxide (TMO) layer, a second TMO layer and a second electrode. The first electrode includes tungsten (W). The first TMO layer is disposed on the first electrode and includes titanium (Ti). The second TMO layer is disposed on the first TMO layer and includes silicon (Si). The second electrode is disposed on the second TMO layer and does not include W. The first TMO layer has a dielectric constant greater than that of the second TMO layer.

According to another embodiment of the present disclosure, a method for fabricating a resistive memory device is provided, wherein the method includes steps as follows: Firstly, a first electrode including W is provided. Next, a first TMO layer including Ti is formed on the first electrode. A second TMO layer including Si and having a dielectric constant less than that of the first TMO layer is formed on the first TMO layer. A second electrode that does not includes W is formed on the second TMO layer.

In accordance with the embodiments of the present disclosure, a resistive memory device and the method for fabricating the same are provided. The resistive memory device includes a stack structure constituted by a W-containing first electrode, a Ti-containing first TMO layer, a Si-containing second TMO layer and a W-free second electrode stacked in sequence.

In some embodiments, the stack structure composed by the certain materials and arranged in a certain sequence as mentioned above can decrease the forming voltage of the resistive memory device, whereby the power consumption of the resistive memory device can be reduced to provide a low-power solution to an electronic device applying it. In some other embodiments, the resistive memory device may be available for multiple-level programming/reset operations. When the resistive memory device is subjected to a plurality of electric pulses having an identical pulse width and a multilevel voltage stepping up from low level to high, the resistive memory device applying the stack structure may have a multiple-resistance state corresponding to the multilevel voltage, wherein each resistance state can be used for storing a single bit of information. Such that the resistive memory device can be capable of storing more than a single bit of information, whereby the bit density of the resistive memory device can be significantly improved. In yet other embodiments, the resistive memory device with the multiple-resistance state can be used as an analog switch involved in an analog neuromorphic circuit for a neural network application.

### BRIEF DESCRIPTION OF THE DRAWINGS

The above and other aspects of the disclosure will become better understood with regard to the following detailed description of the preferred but non-limiting embodiment(s). The following description is made with reference to the accompanying drawings.

FIGS. 1A to 1E are cross-sectional views illustrating the processing structures for fabricating a resistive memory device, in accordance with one embodiment of the present disclosure;

FIGS. 2A to 2B are cross-sectional views illustrating portions of the processing structures for fabricating a resistive memory device, in accordance with another embodiment of the present disclosure;

FIGS. 3A to 3F are cross-sectional views illustrating portions of the processing structures for fabricating a resistive memory device, in accordance with yet another embodiment of the present disclosure;

FIG. 4 is a diagram illustrating the cumulative distribution function (CDF) of a ReRAM cell applying the resistive memory device that is provided by the method described in FIGS. 1A to 1E under different operation conditions in accordance with one embodiment of the present disclosure; and

FIG. 5 is a diagram illustrating the CDFs of the ReRAM cell after subjected to different electrical pluses in sequence during different reset operations in accordance with another embodiment of the present disclosure.

### DETAILED DESCRIPTION OF THE INVENTION

A resistive memory device and the method for fabricating the same are provided to reduce the forming voltage of the resistive memory and enhance the memory density thereof. Several embodiments of the present disclosure are disclosed below with reference to accompanying drawings.

However, the structure and contents disclosed in the embodiments are for exemplary and explanatory purposes only, and the scope of protection of the present disclosure is not limited to the embodiments. Designations common to the accompanying drawings and embodiments are used to indicate identical or similar elements. It should be noted that the present disclosure does not illustrate all possible embodiments, and anyone skilled in the technology field of the invention will be able to make suitable modifications or changes based on the specification disclosed below to meet actual needs without breaching the spirit of the invention. The present disclosure is applicable to other implementations not disclosed in the specification. In addition, the drawings are simplified such that the content of the embodiments can be clearly described, and the shapes, sizes and scales of elements are schematically shown in the drawings for explanatory and exemplary purposes only, not for limiting the scope of protection of the present disclosure.

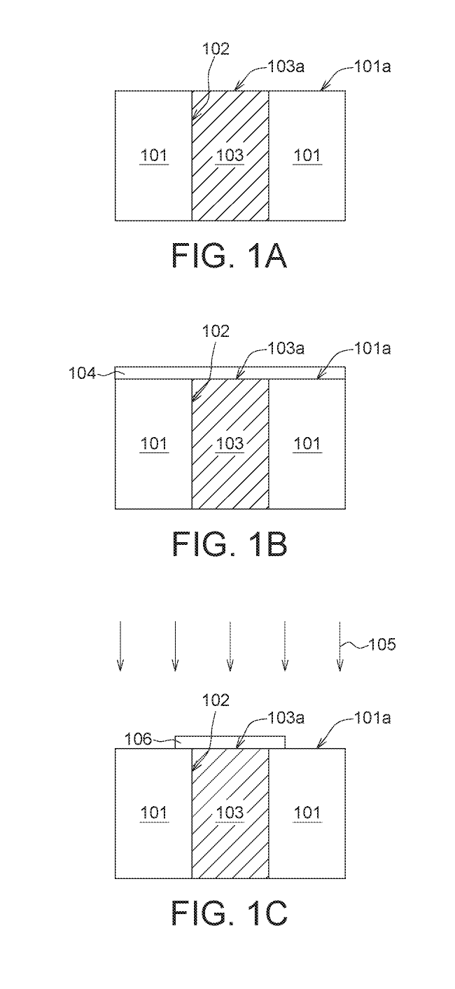

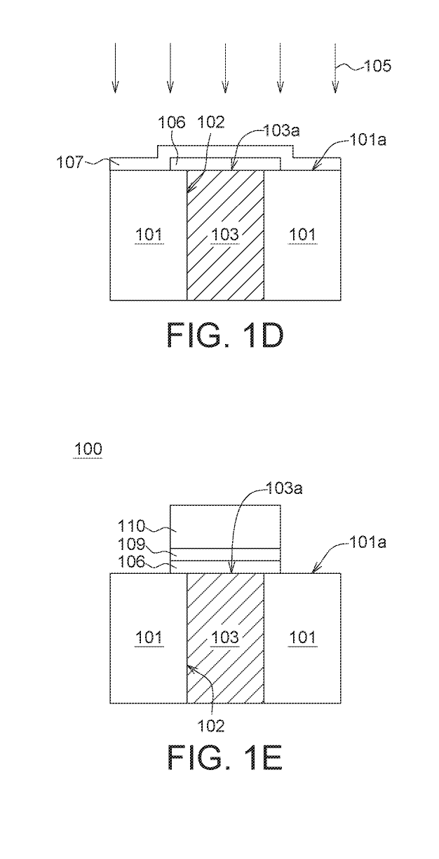

FIGS. 1A to 1E are cross-sectional views illustrating the processing structures for fabricating a resistive memory device 100, in accordance with one embodiment of the present disclosure. The method for forming the resistive memory 100 includes steps as follows: Firstly, a Si-containing substrate 101 is provided. In some embodiments of the present disclosure, the Si-containing substrate 101 may be a polysilicon substrate doped or undoped with (n type or p type) iron implants. In some embodiments of the present disclosure, the Si-containing substrate 101 can be a layer made of a Si-containing dielectric material. In the preset embodiment, the Si-containing substrate 101 can be an inter-layer dielectric layer (ILD) made of silicon oxide (SiOx) disposed on a polysilicon substrate (not shown) (see FIG. 1A).

Next, at least one opening 102 is formed in the Si-containing substrate 101 by a patterning process performed on the top surface 101a of the Si-containing substrate 101. The opening 102 is then fulfilled by a W-containing material. A planarization process, such as a chemical-mechanical planarization (CMP) using the Si-containing substrate 101 as a stop layer is then performed to remove a portion of the W-containing material and form a first electrode 103 in the opening 102, wherein the first electrode 103 may have a top surface 103a substantially conplanar to the top surface 101a of the Si-containing substrate 101 (see FIG. 1A).

In some embodiments of the present disclosure, the opening 102 can be a through-hole passing through the Si-containing substrate 101. The first electrode 103 is made of W. In the present embodiment, the first electrode 103 can be a via plug penetrated through the ILD (Si-containing substrate 101).

A first TMO layer 106 containing Ti is then formed on the first electrode 103. In some embodiments of the present disclosure, the first TMO layer 106 may include titanium oxide (TiOx). In the present embodiment, the forming of the first TMO layer 106 includes steps as follows:

A Ti layer 104 is formed on the top surface 101a of the Si-containing substrate 101 by a metal deposition process (see FIG. 1B). A portion of the Ti layer 104 is then removed by an etching process to exposes a portion of the top surface 101a of the Si-containing substrate 101 and to make the remaining portion of the Ti layer 104 covering the top surface 103a of the first electrode 103 and a portion of the top surface 101a of the Si-containing substrate 101. Subsequently, the remaining portion of the Ti layer 104 is subjected to a bombard of an oxygen-containing plasma 105, whereby the remaining portion of the Ti layer 104 is oxidized to form a first TMO layer 106 (see FIG. 1C). In some embodiments of the present disclosure, the first TMO layer 106 may have a thickness ranging from 1 nanometer (nm) to 12 nm.

During the forming of the first TMO layer 106, the exposed top surface 101a of the Si-containing substrate 101 can be simultaneously bombarded by the oxygen-containing plasma 105, and a plurality of ionized SiOx (e.g. silicon dioxide, SiO₂) or TiOx (e.g. titanium dioxide, TiO₂) atoms coming from the top surface 101a of the Si-containing substrate 101 and the top surface of the Ti layer 104 can be accelerated to dislodge and eject there from and mixing within the oxygen-containing plasma 105. The ionized SiOx or TiOx atoms are then re-sputtered on to the top surface 101a of the Si-containing substrate 101 and the top surface of the first TMO layer 106 to form a Ti-containing sputtering layer 107 (see FIG. 1D). In some embodiments of the present disclosure, the Ti-containing sputtering layer 107 may include titanium-silicon oxide (TiSiOx).

Thereinafter, a W-free conductive layer 108 is formed on the Ti-containing sputtering layer 107, and portions of the W-free conductive layer 108 and the Ti-containing sputtering layer 107 are removed by at least one etching process (not shown) to partially expose the top surface 101a of the Si-containing substrate 101, wherein the remaining portions of the Ti-containing sputtering layer 107 and the W-free conductive layer 108 that align and cover the first TMO layer 106 can respectively serve as a second TMO layer 109 and a second electrode 110 stacked on the first TMO layer 106.

In some embodiments of the present disclosure, the second electrode 110 can be made by a conductive material that does not include W. The W-free conductive material used to form the second electrode 110 may selected from a group consisting of titanium nitride (TiN), copper (Cu), aluminum (Al), gold (Au), silver (Ag), platinum (Pt) and the arbitrary combinations thereof. The second TMO layer 109 may have a thickness ranging from 1 nm to 6 nm.

After a series downstream processes are carried out, the resistive memory device 100 as depicted in FIG. 1E can be implemented. In the present embodiment, the first TMO layer 106 directly contacts to both the first electrode 103 and the second TMO layer 109; and the second electrode 110 directly contacts to the second TMO layer 109.

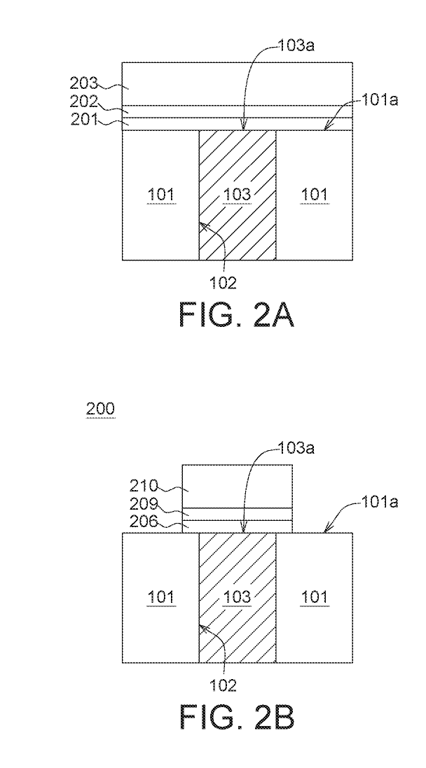

FIGS. 2A to 2B are cross-sectional views illustrating portions of the processing structures for fabricating a resistive memory device 200, in accordance with another embodiment of the present disclosure. The method for forming the resistive memory 200 includes steps as follows: Firstly, a Si-containing substrate 101 is provided; and a first electrode 103 is then formed in the Si-containing substrate 101. In the present embodiment, since the processes for forming the Si-containing substrate 101 and the first electrode 103 are identical to the processes aforementioned in FIG. 1A, thus it will not redundantly describe herein.

Next, a TiOx layer 201, a TiSiOx layer 202 and a W-free conductive layer 203 are formed in sequence on the top surface 101a of the Si-containing substrate 101 (see FIG. 2A) by a plurality of deposition processes (not shown). In the present embodiment, the TiOx layer 201 may have a thickness ranging from 1 nm to 12 nm; and the TiSiOx layer 202 may have a thickness ranging from 1 nm to 6 nm.

Portions of the W-free conductive layer 203, the TiSiOx layer 202 and the TiOx layer 201 are then removed by at least etching process (not shown) to expose a portion of the top surface 101a of the Si-containing substrate 101, wherein the remaining portions of the TiOx layer 201, the TiSiOx layer 202 and the W-free conductive layer 203 that cover on the top surface 103a of the first electrode 103 can respectively serve as a first TMO layer 206, a second TMO layer 209 and a second electrode 210. After a series downstream processes are carried out, the resistive memory device 200 as depicted in FIG. 2B can be implemented.

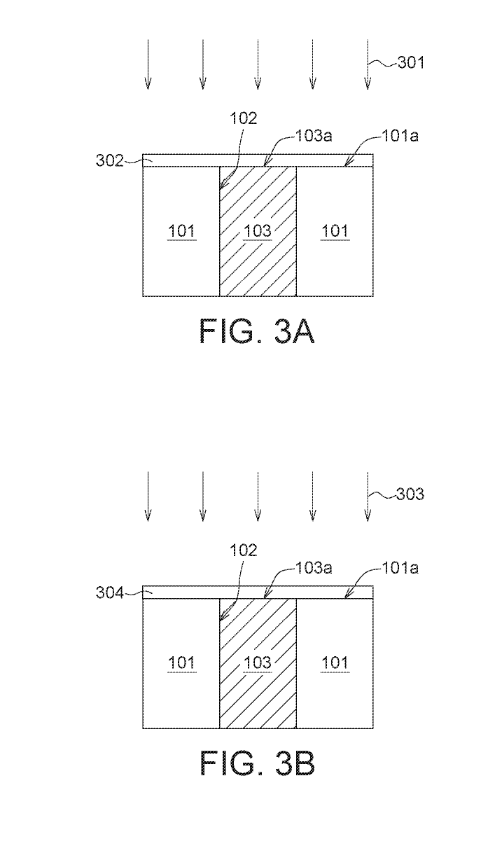

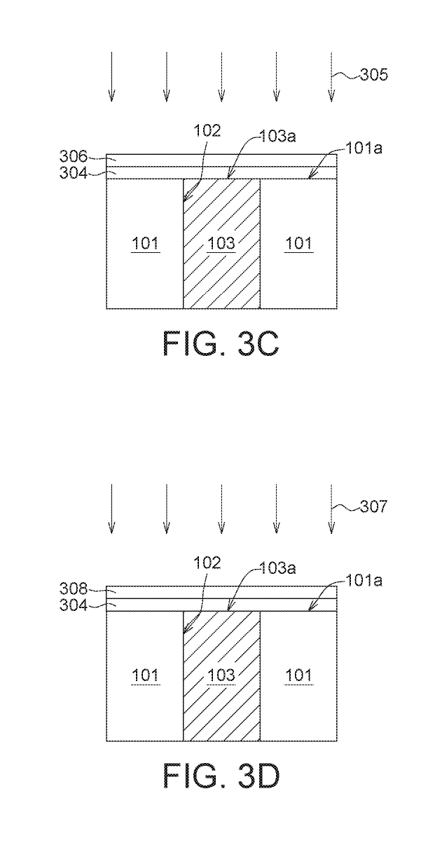

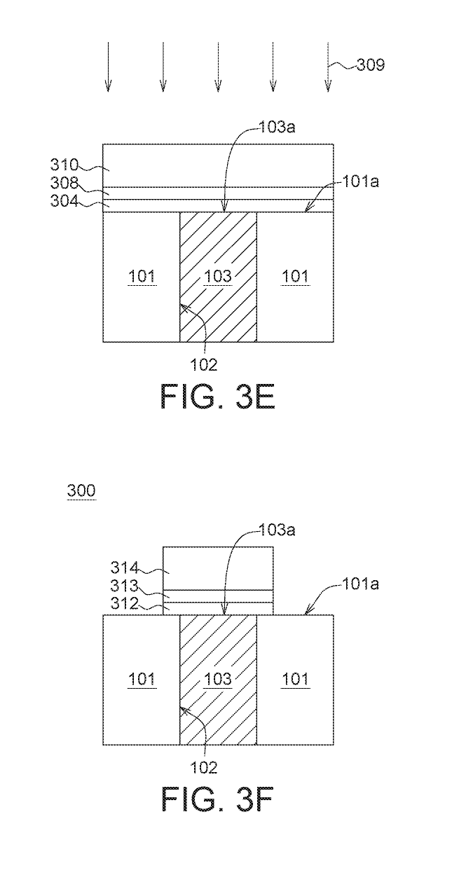

FIGS. 3A to 3F are cross-sectional views illustrating portions of the processing structures for fabricating a resistive memory device 300, in accordance with yet another embodiment of the present disclosure. The method for forming the resistive memory 300 includes steps as follows: Firstly, a Si-containing substrate 101 is provided; and a first electrode 103 is then formed in the Si-containing substrate 101. In the present embodiment, since the processes for forming the Si-containing substrate 101 and the first electrode 103 are identical to the processes aforementioned in FIG. 1A, thus it will not redundantly describe herein.

Next, a Ti layer 302 is formed on the top surface 101a of the Si-containing substrate 101 by a metal deposition process 301 (see FIG. 3A). The Ti layer 302 is then subjected to an oxidization process 304 to form a TiOx layer 304 on the top surface 103a of the first electrode 103 (see FIG. 3B). A titanium silicide layer 306 is then formed on the TiOx layer 304 by another deposition process 305 (see FIG. 3C). The titanium silicide layer 306 is then subjected to an oxidization process 307 to form a TiSiOx layer 308 on the TiOx layer 304 (see FIG. 3D). A titanium nitride (TiN) layer 310 is formed on the TiSiOx layer 308 by yet another deposition process 309 (see FIG. 3E).

Portions of the TiOx layer 304, the TiSiOx layer 308 and the TiN layer 310 are then removed by at least etching process (not shown) to expose a portion of the top surface 101a of the Si-containing substrate 101, wherein the remaining portions of the TiOx layer 304, the TiSiOx layer 308 and the TiN layer 310 that cover on the top surface 103a of the first electrode 103 can respectively serve as a first TMO layer 312, a second TMO layer 313 and a second electrode 314. After a series downstream processes are carried out, the resistive memory device 300 as depicted in FIG. 3F can be implemented.

Each of the resistive memory devices 100, 200 and 300 fabricated by the methods discussed above can be integrated with other semiconductor to form a memory cell unit. For example, in some embodiments of the present disclosure, each of the resistive memory devices 100, 200 and 300 can be integrated with a transistor device to form a ReRAM cell with a one-transistor/one-resistor (1T1R) structure.

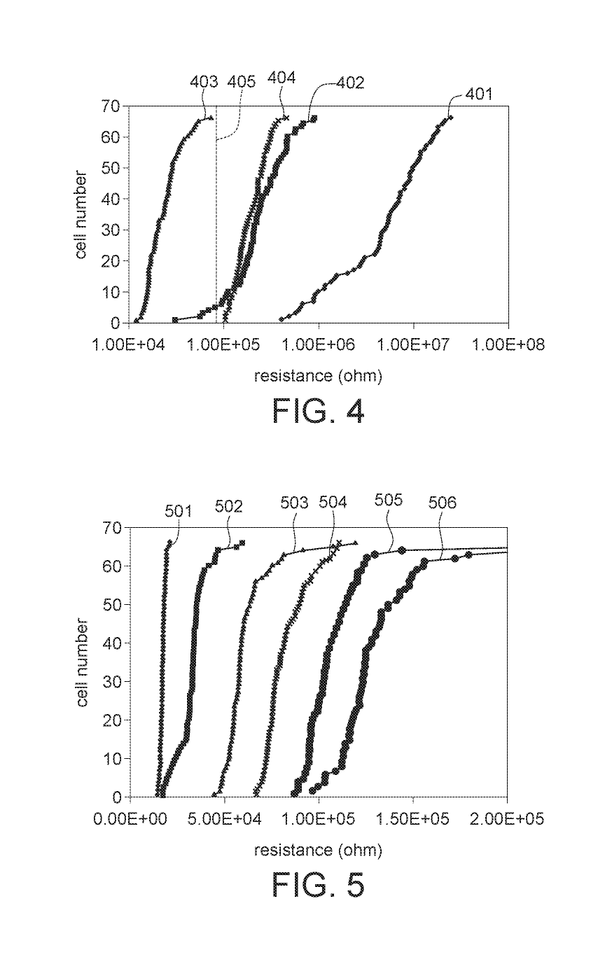

FIG. 4 is a diagram illustrating the cumulative distribution function (CDF) of a ReRAM cell applying the resistive memory device 100 that is provided by the method described in FIGS. 1A to 1E under different operation conditions in accordance with one embodiment of the present disclosure. The horizontal axis indicates the resistance of the ReRAM cell and the vertical axis indicates the cumulative number of the ReRAM cell. The curve 401 represents the CDF of the initial resistance distribution of the ReRAM cell. The curve 402 represents the CDF of the resistance, after a forming voltage is applied to the ReRAM cell. The curve 403 represents the CDF of the resistance after a set voltage is applied to the ReRAM cell. The curve 404 represents the CDF of the resistance after a reset voltage is applied to the ReRAM cell.

According to FIG. 4, when the ReRAM cell is set, it has a distribution area with a lower resistance (see the curve 403); when the ReRAM cell is reset, it has a distribution area with a higher resistance (see the curve 404); and there is a gap separating the lower resistance distribution area from the higher resistance distribution area. The state of the ReRAM cell obtained by determining whether the resistance of the ReRAM cell is greater than a predetermined critical resistance 405 with in the gap can be utilized to indicate digital signal (i.e. “0” or “1”), thereby allowing for data storage.

In some embodiments of the present disclosure, a forming voltage, a set voltage and a reset voltage having a pulse width of 1000 ns can be applied through the bit line to operate the ReRAM cell, wherein the word line can be driven to 5V. In the present embodiment, the forming voltage of the ReRAM cell is about 1.7V; the set voltage and the reset voltage thereof can be greater than the forming voltage and less than 2V, which can be less than that of the prior art ReRAM cell. Accordingly, the power consumption of the ReRAM cell applying the resistive memory device 100 can be reduced in comparison to the prior art.

FIG. 5 is a diagram illustrating the CDFs of the ReRAM cell after subjected to different electrical pluses in sequence during different reset operations in accordance with another embodiment of the present disclosure. The curves 506-506 respectively represent the CDFs of the ReRAM cell after the ReRAM cell is subjected to various electrical pluses in sequence during different reset operations. In some embodiments of the present disclosure, the electrical pluses applied to the ReRAM cell can be varied by adjust its voltage applied to the word line and the bit line. In the present embodiment, the curves 506-506 respectively represents the CDFs of the ReRAM cell when the ReRAM cell is sequentially subjected to a plurality of electrical pulses with an identical pulse widths and a multilevel voltage stepping up from low level to high, wherein the electrical pulses may be provide by respectively applying voltage about 2V, 2.5V, 3.5V, 40V and 4.5V to the word line, and applying a voltage ranging from 1 V to 2V to the bit line.

According to FIG. 5, after subjected to each of the electrical pluses the ReRAM cell may have an average resistance (i.e. 18K Ohm (Ω), 30KΩ, 50KΩ, 70KΩ, 90KΩ and 110KΩ) corresponding to each voltage level of the multilevel voltage, and the CDFs of the ReRAM cell (see curves 506-506) may have a multiple-resistance state. In other words, the average resistances of the ReRAM cell within different resistance states can be steppingly increased corresponding to the cumulated energy applied to the ReRAM cell. In some embodiments of the present disclosure, the ReRAM cell provided by the embodiments of the present disclosure can be used to serve as an analog switch involved in an analog neuromorphic circuit for a neural network application which can provided an analog behavior model (ABM) to conduct a neuromorphic computing.

In accordance with the embodiments of the present disclosure, a resistive memory device and the method for fabricating the same are provided. The resistive memory device includes a stack structure constituted by a W-containing first electrode, a Ti-containing first TMO layer, a Si-containing second TMO layer and a W-free second electrode stacked in sequence.

In some embodiments, the stack structure composed by the certain materials and arranged in a certain sequence as mentioned above can decrease the forming voltage of the resistive memory device, whereby the power consumption of the resistive memory device can be reduced to provide a low-power solution to an electronic device applying it. In some other embodiments, the resistive memory device may be available for multiple-level programming/reset operations. When the resistive memory device is subjected to a plurality of electric pulses having an identical pulse width and a multilevel voltage stepping up from low level to high, the resistive memory device applying the stack structure may have a multiple-resistance state corresponding to the multilevel voltage, wherein each resistance state can be used for storing a single bit of information. Such that the resistive memory device can be capable of storing more than a single bit of information, whereby the bit density of the resistive memory device can be significantly improved. In yet other embodiments, the resistive memory device with the multiple-resistance state can be used as an analog switch involved in an analog neuromorphic circuit for a neural network application.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A resistive memory device comprising:
a first electrode, comprising tungsten (W);
a first transition metal oxide (TMO) layer, disposed on the first electrode and comprising titanium oxide (TiOx);
a second TMO layer, disposed on the first TMO layer and comprising silicon (Si); and
a second electrode, disposed on the second TMO layer and not comprising W;
wherein the first TMO layer has a dielectric constant greater than that of the second TMO layer.

2. The resistive memory device according to claim 1, wherein the second TMO layer comprises titanium-silicon oxide (TiSiOx).

3. The resistive memory device according to claim 2, wherein the first TMO layer has a thickness ranging from 1 nanometer (nm) to 12 nm, and the second TMO layer has a thickness ranging from 1 nm to 6 nm.

4. The resistive memory device according to claim 1, wherein the first TMO layer directly contacts to the second TMO layer.

5. The resistive memory device according to claim 1, wherein the second electrode comprises a W-free conductive material selected from a group consisting of titanium nitride (TiN), copper (Cu), aluminum (Al), gold (Au), silver (Ag), platinum (Pt) and the arbitrary combinations thereof.

6. The resistive memory device according to claim 1, wherein after subjected to a plurality of electrical pluses in sequence, the resistive memory device has a multiple-resistance state.

7. A method for fabricating a resistive memory device, comprising:
providing a first electrode comprising W;
forming a first TMO layer comprising Ti on the first electrode;
forming a second TMO layer comprising Si on the first TMO layer, wherein the first TMO layer has a dielectric constant greater than that of the second TMO layer; and
forming a second electrode not comprising W on the second TMO layer.

8. The method according to claim 7, wherein the step of providing the first electrode comprising W comprises:
forming an opening in a Si-containing substrate;
fulfilling the opening by a W-containing material; and
performing a planarization process using the Si-containing substrate as a stop layer to remove a portion of the W-containing material.

9. The method according to claim 8, wherein the forming of the first TMO layer comprises:
forming a patterned Ti layer covering the first electrode and a portion of the Si-containing substrate; and
bombarding the patterned Ti layer with an oxygen-containing plasma.

10. The method according to claim 9, wherein the forming of the second TMO layer comprises steps of bombarding the first TMO layer and a portion of the Si-containing substrate not covered by the first TMO layer with the oxygen-containing plasma.

11. The method according to claim 8, wherein the forming of the first TMO layer, the second TMO layer and the second electrode comprises:
forming a TiOx layer, a TiSiOx layer and a W-free conductive layer on the first electrode and the Si-containing substrate in sequence; and
patterning the TiOx layer, the TiSiOx layer and the W-free conductive layer to expose a portion of the Si-containing substrate.

12. The method according to claim 11, wherein the forming of the TiOx layer, the TiSiOx layer and the W-free conductive layer comprises:
performing a first deposition process to form the TiOx layer on the first electrode and the Si-containing substrate;
performing a second deposition process to form the TiSiOx layer on the TiOx layer; and
performing a third deposition process to form the W-free conductive layer on the TiOx layer.

13. The method according to claim 11, wherein the forming of the TiOx layer, comprises:
depositing a Ti layer on the first electrode and the Si-containing substrate; and
oxidizing the Ti layer.

14. The method according to claim 13, wherein the forming of the TiSiOx layer, comprises:
depositing a titanium silicide layer on the TiOx layer; and
oxidizing the titanium silicide layer.
